(19) United States
(12) Patent Application Publication
(10) Pub. No.: US 2016/0109307 A1
(43) Pub. Date: Apr. 21, 2016

(54) SYSTEM AND METHOD FOR SPIRAL CONTACT FORCE SENSORS

(71) Applicant: QUALCOMM Incorporated, San Diego, CA (US)

(72) Inventor: James Pieronek, San diego, CA (US)

(21) Appl. No.: 14/866,699

(22) Filed: Sep. 25, 2015

Related U.S. Application Data
(60) Provisional application No. 62/065,546, filed on Oct. 17, 2014.

(51) Int. Cl. G01L 1/22; G06F 3/041; H05K 3/10

(52) U.S. Cl. CPC G01L 1/2287; H05K 3/10; G06F 3/0414

(57) ABSTRACT

A system and method for spiral contact force sensors includes a force sensor including a substrate, a first contact having a first spiral pattern formed on the substrate, a second contact having a second spiral pattern formed on the substrate, the first and second spiral patterns being interleaved, and a force sensitive material disposed so as to provide a variable resistance between the first contact and the second contact based on a force applied to the force sensor, wherein a force-resistance relationship of the force sensor is continuous as a radius of a circular region where the force is applied to the force sensor varies.

### RELATED APPLICATIONS

The present disclosure claims priority to U.S. Provisional Application 62/065,546, filed on Oct. 17, 2014, which is herein incorporated by reference in its entirety.

### BACKGROUND

The present disclosure relates generally to input methods for computing systems, and more particularly to force sensors using spiral contacts.

Many of today's applications and devices call for the use of a force input sensor that may be used to detect the amount of force applied by a finger and/or a stylus on an input device such as a touch pad, touch screen, and/or the like. Many force input sensors use a force sensitive material having an electrical property, such as resistance, that changes with the amount of force applied. However, many of the force sensors currently in use to not provide a continuous response to increasing force.

Accordingly, it would be desirable to provide systems and methods for force input sensors that provide a continuous output over a large range of applied forces.

### SUMMARY

According to some implementations a system and method for spiral contact force sensors may include a force sensor including a substrate, a first contact having a first spiral pattern formed on the substrate, a second contact having a second spiral pattern formed on the substrate, the first and second spiral patterns being interleaved, and a force sensitive material disposed so as to provide a variable resistance between the first contact and the second contact based on a force applied to the force sensor. A force-resistance relationship of the force sensor is continuous as a radius of a circular region where the force is applied to the force sensor varies.

### BRIEF DESCRIPTION OF THE DRAWINGS

FIG. 1 is a simplified diagram of a stylus according to some implementations.

FIG. 2 is a simplified diagram of a force sensor using contacts and force sensitive material on a substrate according to some implementations.

FIG. 3 illustrates a cross-sectional view of a force sensor with an actuator tip.

FIG. 4 shows a simplified diagram of force-voltage relationship for force sensors as illustrated in FIG. 2.

FIGS. 5A-5G are simplified diagrams of contact patterns according to some implementations that produce a more continuous response according to some implementations.

FIG. 6 illustrates force-voltage relationships with sample contact patterns shown in FIGS. 5A-5G.

### DETAILED DESCRIPTION

In the following description, specific details are set forth describing some implementations consistent with the present disclosure. It will be apparent, however, to one skilled in the art that some implementations may be practiced without some or all of these specific details. The specific implementations disclosed herein are meant to be illustrative but not limiting. One skilled in the art may realize other elements that, although not specifically described here, are within the scope and the spirit of this disclosure. In addition, to avoid unnecessary repetition, one or more features shown and described in association with one implementation may be incorporated into other implementations unless specifically described otherwise or if the one or more features would make an implementation non-functional. Relative terms such as “above” or “below” refer only to relative positioning with respect to the orientation of the figure and do not have further physical meaning.

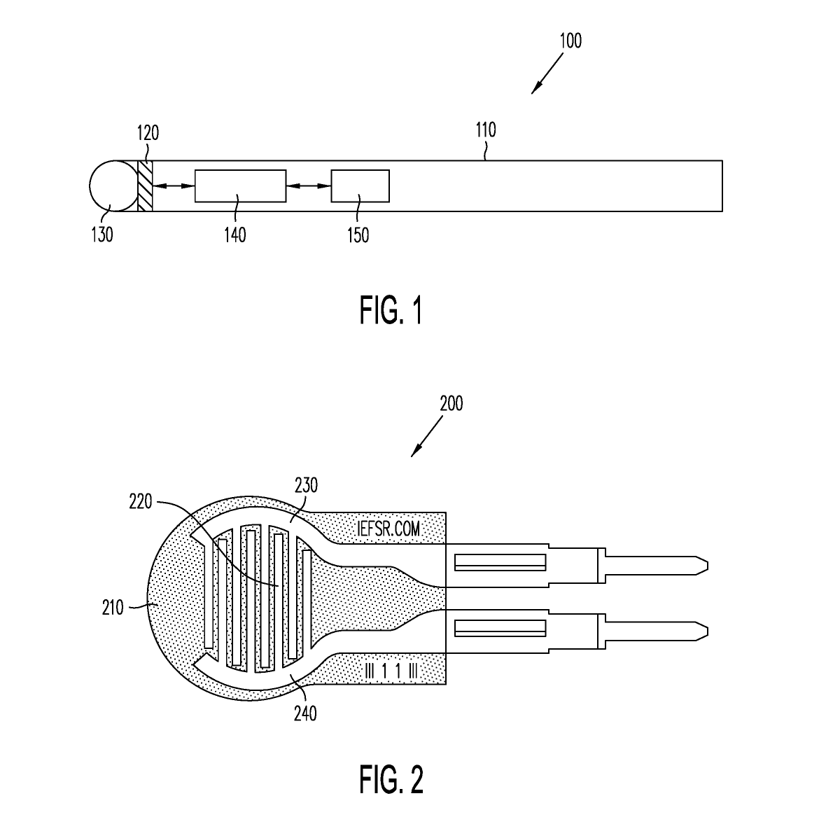

FIG. 1 is a simplified diagram of a stylus 100 according to some implementations. As shown in FIG. 1, stylus 100 includes a body 110. Located near one end of body 110 is a force sensor 120 positioned between body 110 and an actuator tip 130. In some examples, actuator tip 130 may be hard pointed and have a roughly spherical or similar shape. In some examples, actuator tip 130 may include a compliant material, such as rubber, that may deform as more force is applied to actuator tip 130. Stylus 100 further includes a sensing circuit 140 for evaluating and/or measuring the force applied by actuator tip 130 on force sensor 120. Coupled to sensing circuit 140 is a communications circuit 150 for providing the results of the force measurements from sensing circuit 140 to other circuits (not shown). In some examples, the other circuits may include a computer, a tablet, a smart phone, a personal data assistant (PDA), some type of mobile device, and/or the like. In some examples, communications circuit 150 may be wired and/or wireless.

A computing system using stylus 100 as an input device may use force sensor 120 to determine the amount of force being applied by the user on actuator tip 130 of stylus 100. In some examples, the sensed force may be used to determine a width of a line being drawn by stylus 100. In some examples, it is generally useful for force sensor 120 to have a smooth and continuous relationship between the actual force applied and the force measurement determined by sensing circuit 140 so that an application using the sensed force to determine line widths may accurately produce the line widths consistent with the force applied on stylus 100.

Several inexpensive force sensitive materials are available for use in force sensor 120. Such materials, for example, can change their resistance in response to a force applied to the materials. In some examples, an inexpensive way to utilize these force sensitive materials is to press them against a circuit board or other substrate that has two exposed conductive contacts. FIG. 2 is a simplified diagram of a force sensor 200 using contacts and force sensitive material on a substrate 210 according to some implementations. In some examples, force sensor 200 may be suitable for use as force sensor 120. As shown in FIG. 2, substrate 210 includes a force sensitive material 220 that is able to adjust the resistance between patterned contacts 230 and 240 depending upon the amount of force applied to the force sensitive material 220 and/or how large an area of the force sensitive material 220 to which the force is applied. In some examples, the force sensitive material 220 may be deposited between the patterned contacts 230 and 240. In some examples the force sensitive material 220 may be deposited on a layer above or below the patterned contacts 230 and 240. In some examples, the force sensitive material 220 may be deposited on a second substrate, such as a plastic substrate, (not shown) which may be pressed against the patterned contacts 230 and 240 when force is applied. In some examples, a current may be passed though the force sensitive material 220 via the patterned contacts 230 and 240 such that that amount of current that flows between the patterned contacts 230 and 240 via the compressed force sensitive material 220 changes as force is applied to the force sensitive material 220. In some examples, the voltage across the patterned contacts 230 and 240 may vary with the resistance produced by the force sensitive material 220. In some examples, a voltage may be applied across the patterned contacts 230 and 240, which will produce a current that varies inversely with the resistance of the force sensitive material 220.

According to some implementations, a layout of the patterned contacts 230 and 240 on the substrate 210 may significantly influence the operation of the force sensor 200. In some examples, the shape and stiffness of an actuator tip, such as actuator tip 130, that applies force to the force sensitive material 220 and substrate 210 may also influence the operation of force sensor 200. In some examples, when the actuator tip is a hard pointed or hard spherical actuator it may compress a relatively small area at the point of contact on the force sensitive material 220. In some examples, this may produce a rapid change in the resistance of the force sensor 200 between the patterned contacts 230 and 240, which may easily reach the limits of force sensitive material's 220 ability to change resistance as additional force is applied. In some examples, when measurement of a large range of forces is desired, a roughly spherical actuator tip made of a compliant material, such as rubber, may be used so that as increasing forces are applied by the actuator tip, the actuator tip may deform and spread out over a larger area of the patterned conductors 230 and 240. In some examples, this may allow force sensor 200 to have a more linear response as more and more of the force sensitive material 220 between the patterned conductors 230 and 240 is pressed by the actuator tip as the force increases. In some examples, the layout of the patterned contacts 230 and 240 may influence the resistance change of force sensor 200 as much as, and sometimes more than, the force-resistance response of the force sensitive material alone.

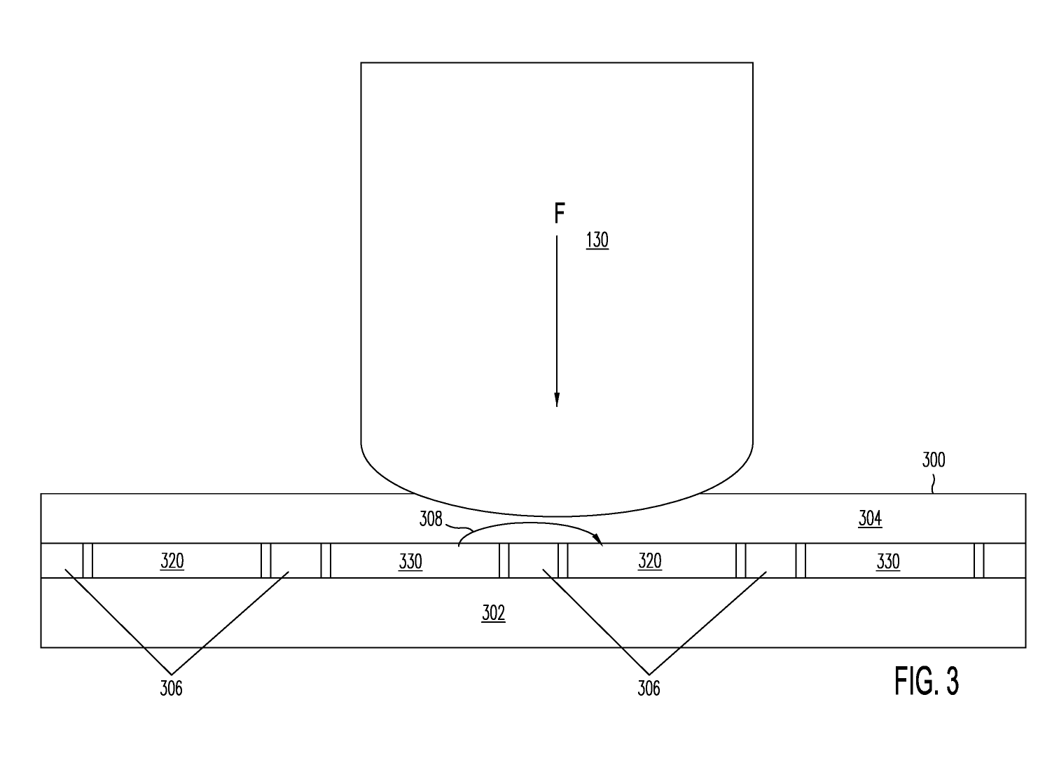

FIG. 3 illustrates a cross sectional view of a force sensor 300 with actuator tip 130 applying a force to force sensor 300. Force sensor 300 may depict a force sensor such as sensor 200 shown in FIG. 2 or may be a force sensor according to implementations of the present invention. As shown in FIG. 3, force sensor 300 includes interleaved electrodes 320 and 330 deposited on an insulating substrate 302. Electrodes 320 and 330 can be formed of copper, for example, or other conducting material and may be separated by insulators 306. In some cases, insulators 306 may be formed of the solder mask that is deposited during deposition of electrodes 320 and 330, or a separate insulator may be formed. In the example illustrated in FIG. 3, a force sensitive resistive material 300 is deposited over electrodes 320 and 330. As discussed above, force sensitive resistive material 300 has a resistance that changes with applied force. As a result, the current 308 between electrodes 330 and 320 varies with the applied force from actuator tip 130. As discussed above, force sensitive material 300 may, in some implementations, be deposited between electrodes 320 and 330 or beneath electrodes 320 and 330. In some implementations, force sensitive material 300 may be deposited on a separate substrate and brought into contact with electrodes 320 and 330.

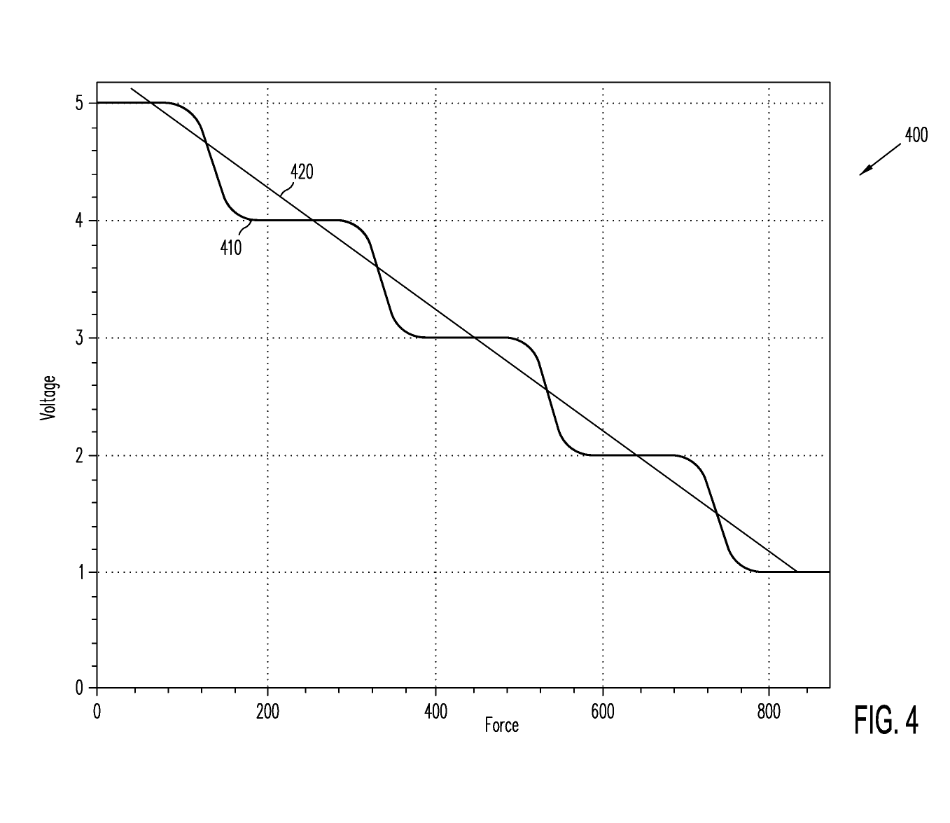

In some cases, manufacturers of force sensitive materials may supply suggested contact patterns in their product literature and application notes. These patterns generally fall into three categories: inter-digitated fingers, square spirals, and circular trees. For example, the contact pattern in FIG. 2 is representative of an inter-digitated fingers pattern. In practice, each of these common patterns may provide a somewhat staircase shaped response over large force ranges, as is illustrated in response 410 illustrated in FIG. 4. This response is due to the fact that as the actuator tip 130 is pressed and spreads out over a roughly circular region, the actuator tip 130 encounters the next set of contacts in the arrangement. As each next set of contacts or fingers is pressed, a rapid drop in resistance of the force sensor 200 may result because the addition of the new contacts or fingers may create a new path for current flow. Therefore, with each of the three types of patterns described above, it may be difficult to achieve a truly continuous relationship between force and resistance, voltage, or current over a wide range of applied force values without incurring some stair step distortion in the resulting measurement.

FIG. 4 is a simplified diagram of force-voltage relationships 400. As shown in FIG. 4, a curve 410 may be consistent with the force-resistance relationship from any of the three types of commonly used contact patterns, such as the contact pattern shown in FIG. 2. Curve 410 shows the stair step distortion pattern, as described above, which is generally undesirable. Each of the vertical jumps in resistance, resulting in a vertical jump in voltage in FIG. 4, in curve 410 may correspond to the inclusion of another contact or finger 320 and 330 within the application area of the actuator tip 130.

In contrast, response curve 420 shown in FIG. 4 shows a more desirable force-voltage relationship. The more continuous response curve 420 avoids the stair step distortion problem of curve 410 and provides a more accurate determination of the force applied, which is a much more desirable response curve for practical force sensors. Implementations of the present invention provide for patterns of contacts that result in a more continuous response curve such as response curve 420 and substantially eliminates the stair-step response curve 410 obtained from force sensors such as force sensor 200.

Although FIG. 4 shows the output from a half-bridge connected sensor, any of the various methods of monitoring the value of the resistance of the sensor can be used. Other methods include, but are not limited to, a full Wheatstone bridge, driving with a constant current or voltage source and measuring current or voltage, using the sensor to control the current flow into a capacitor and measuring the time to transition between two voltage when a step voltage or current is applied, or other methods. As discussed above, force sensor 200 can be configured in a half-bridge configuration. In the half-bridge configuration, a fixed value resistor is arranged in series with the force sensitive resistor. The free end of the fixed resistor is connected to a fixed voltage and the free end of the force sensitive resistor is connected to ground or to the return side of the fixed voltage. The output voltage of force sensor 200 in this case is the voltage across the force sensitive resistor (or the complimentary voltage across the fixed resistor). The half-bridge effectively compares the resistance of the force-sensitive resistor to that of the fixed resistor in order to determine the force.

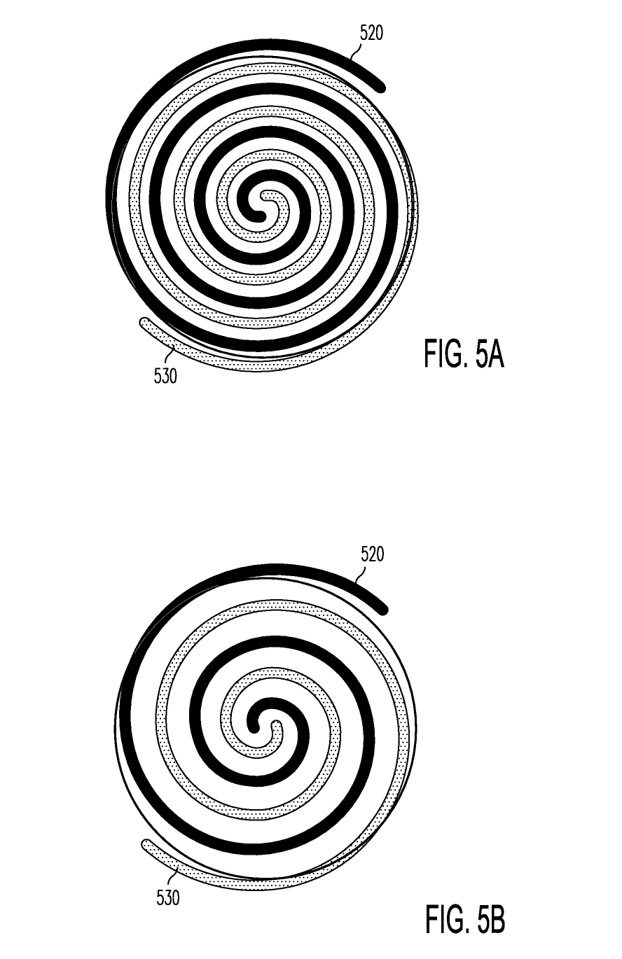

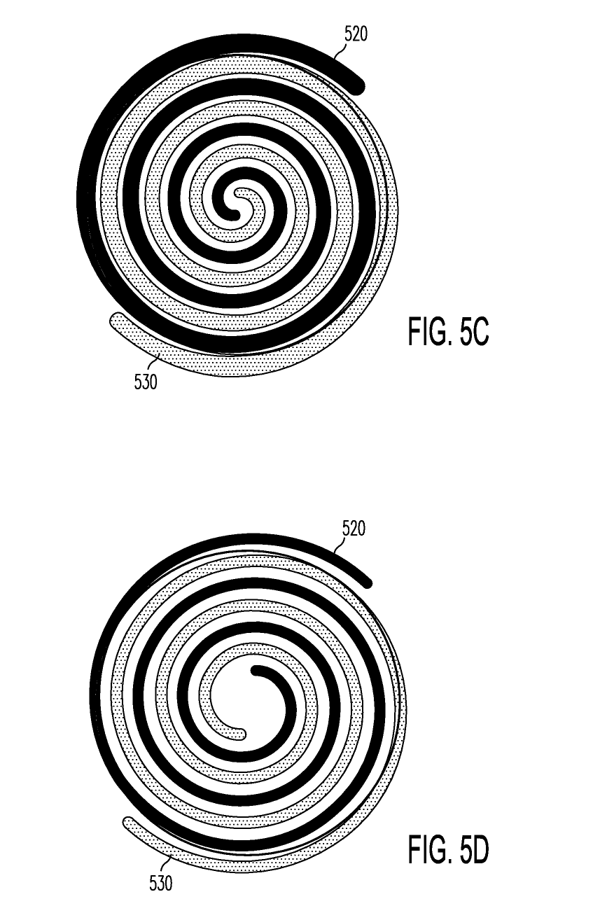

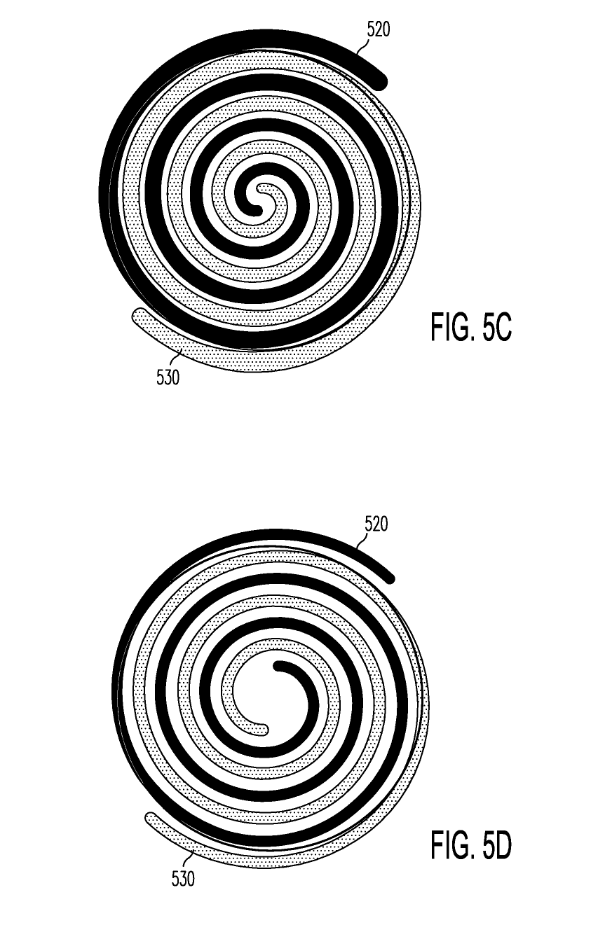

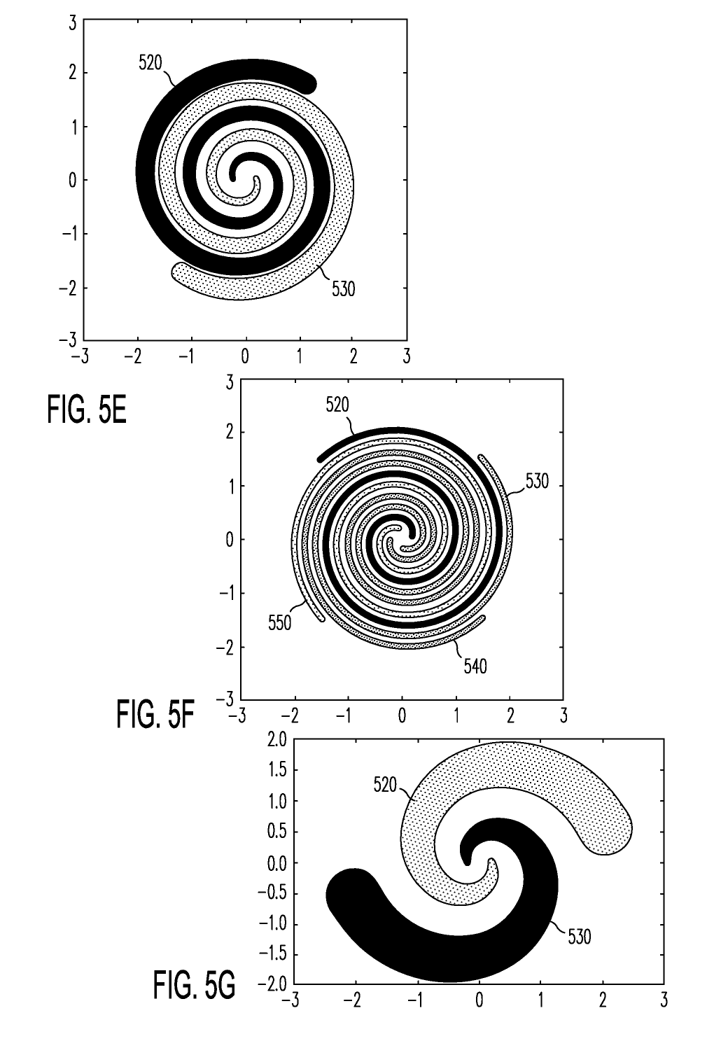

FIGS. 5A-5G are simplified diagrams of contact patterns according to some implementations. Such interleaved spiraling patterns produce a more continuous response curve, can eliminate the stair-step response curve such as response curve 410 depicted in FIG. 4, and can be adjusted to tailor a response curve for better applicability. In FIGS. 5A and 5B, the contact pattern includes a spiral shaped contact 520 interleaved with another spiral shaped contact 530. In some examples, any of the contact patterns of FIGS. 5A-5G may be used to reduce and/or eliminate the stair step discontinuities created by the inter-digitated fingers pattern as shown in FIG. 2, or which is also exhibited by the square spirals and circular tree patterns discussed above. In some examples, each of the contact patterns in FIGS. 5A-5G may provide a response curve closer to response curve 420 than that exhibited by response curve 410. In some examples, any of the contact patterns in FIGS. 5A-5G may be used to replace the contact pattern of force sensor 200 and/or force sensor 120 shown in FIGS. 1 and 2.

FIG. 5A shows an interleaved spiral pattern using two spiral-shaped contacts 520 and 530 with a constant space between. In some examples, the pattern of spirals in FIG. 5A does not present any discontinuities in the conductive area under the actuator tip. As the actuator tip contact area spreads in a circular fashion with increasing applied force, the increasing radius of the contact circle continuously engages more and more of the spiral pattern. Thus, as the radius of the expanding circle of applied force continuously contacts more of the spiral pattern, a continuous response, instead of a step-wise or discontinuous response, in the force sensor output is obtained.

According to some implementations, variations in the spiral pattern may be used to fine tune the response relationship of the force sensor. In some examples, the slope of the response relationship curve may be adjusted by controlling the amount of space between the interleaved spirals 520 and 530. In some examples, the spacing between the spirals 520 and 530 may be increased at an exponential rate as the spirals 520 and 530 expand away from a center point, as shown in the implementation illustrated in FIG. 5B, to reduce the rate at which resistance changes with applied force. In some examples, the slope of the response curve may be adjusted by increasing the thickness of spiral contacts 520 and 530 as the spiral contacts 520 and 530 expand away from a center point while keeping the spacing between spirals a constant as shown in FIG. 5C. In some examples, a minimum force threshold before any resistance change is registered may be created by leaving a center portion of the spiral contacts 520 and 530 without contact material as shown in FIG. 5D.

FIG. 5E illustrates a pattern with interleaved spiral contacts 520 and 530 with line widths that vary with location on the spirals, as illustrated also in FIG. 5C. However, in FIG. 5E the spacing between spirals also varies with location on the spirals while in FIG. 5C the spacing between spirals stays the same. In this fashion, the response curve is adjusted by making the traces of spiral contacts 520 and 530 larger and the gaps between spiral contacts 520 and 530 smaller as distance increases from the origin, which will cause the resistance to drop faster at higher levels of force.

In some implementations, multiple spiral contacts can be used. As shown in FIG. 5F, for example, the pattern is formed by interleaving four spiral contacts 520, 530, 540, and 550. In some implementations, spiral contact 520 can be electrically coupled with spiral contact 540 while spiral contact 530 is electrically coupled to spiral contact 550. Such arrangements can further control the response curve of the resulting force sensor.

FIG. 5G illustrates an example where interleaved spirals are exponential spirals with exponentially increasing line widths. Such an arrangement may further enhance the response curve of the resulting force sensor. Combining patterns in other combinations will also produce an enhanced response.

According to some implementations, spiral patterns may be difficult to draw by hand, so the patterns of spiral contacts illustrated in FIGS. 5A-5G may be drawn with the aid of a computer program that may be used to produce the various spiral patterns in a format that allows them to be pasted and/or imported into a circuit board CAD program. The computer program may be stored on a computer readable medium accessible to the computer. In some examples, the computer program may support the generation of any of the variety of spiral pattern types as shown in FIGS. 5A-5G that are used to tune the performance of the corresponding force sensor.

A spiral in polar coordinates is given by the equation

r=αθⁿ,

where r is the radius from the origin and Θ is the angle. The parameter a sets the initial distance between successive loops of the spiral. The exponent n is set to 1 to create a linear spiral, set to values greater than 1 to create a spiral where the distance between successive loops will increase, and set to values less than 1 to create a spiral where the successive loops get closer together. The parametric rectangular coordinates corresponding to this spiral equation is given by:

x=αθⁿ cos(θ)

y=αθⁿ sin(θ).

Drawing the spiral is accomplished by stepping the values of the parameter Θ from 0 to 2π times the number of loops to be drawn. As each step is calculated, a line is drawn from the previous coordinates to the current coordinates. The start and stop values of the parameter Θ can be adjusted to vary the locations of the beginning and end of each spiral. The width of the spiral contact can be adjusted at each step to create varying width spiral contacts using the equation:

w=b+cθ^{k},

where b is the basic line width. The parameter c is zero where the width of the spiral contact is a constant, positive for increasing width with distance from the origin and negative for decreasing width with distance from the origin. The parameter k can be set to 1 for linearly varying width while set to other values to vary exponentially.

Multiple spirals can be drawn by the program rotating the first spiral around the origin by a rotation angle Φ. A rotation angle Φ of π will result in interleaved spirals as shown in FIG. 4A, for example. Multiple spirals can be obtained by setting the rotation angle Φ to other values, for example the four spiral pattern of FIG. 4F results with a rotation angle Φ of π/2.

A continuous response curve can be obtained, therefore, by setting the parameters a, n, b, c, and k. Determining and drawing two or more spirals with the set parameters will result in an electrode pattern the response curve. Adjustments to the response curve can be affected by adjustments to the parameters a, n, b, c, and k.

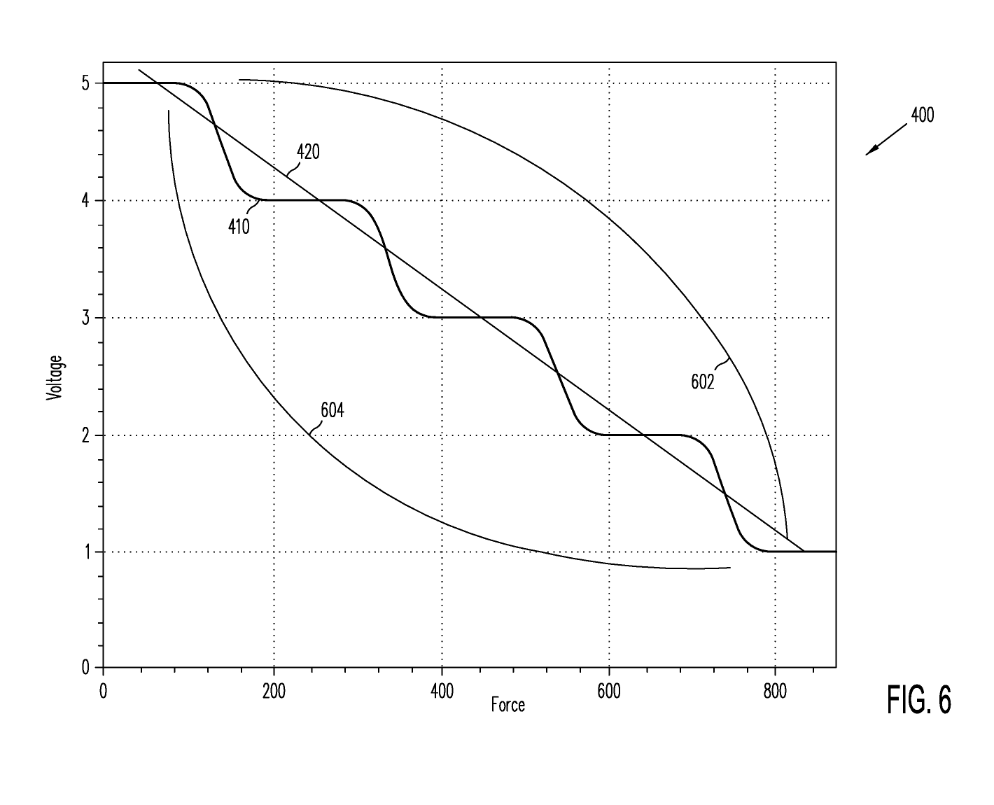

FIG. 6 illustrates further response curves corresponding to spiral patterns according to some implementations of the present invention. Response curve 604 illustrates the voltage from a half-bridge sensor using the pattern of FIG. 5B. Response curve 602 illustrates the voltage from a half-bridge sensor using the pattern of FIG. 5C. Response curve 604 has the advantage that there is greater sensitivity at low forces compared to high forces. Response curve 602 has the advantage that there is greater sensitivity at high forces compared to low forces. FIG. 5B, corresponding to response curve 604, is an exponentially increasing spiral with parameter n about 1.1 and parameter a being a constant. FIG. 5B also has a constant width and thickness (b is constant, c=0 and k is irrelevant). FIG. 5C is an exponentially decreasing spiral with n about 0.95 (parameters a, b, c, and k being the same as in FIG. 5B). In general, there is significant interplay between the force sensitive material, the contact pattern, the shape of the actuator, and the stiffness (durometer) of the actuator.

Although illustrative implementations have been shown and described, a wide range of modification, change and substitution is contemplated in the foregoing disclosure and in some instances, some features of the implementations may be employed without a corresponding use of other features. One of ordinary skill in the art would recognize many variations, alternatives, and modifications.

What is claimed is:

1. A force sensor comprising:
a substrate;
a first contact having a first spiral pattern formed on the substrate;
a second contact having a second spiral pattern formed on the substrate, the first and second spiral patterns being interleaved; and
a force sensitive material disposed so as to provide a variable resistance between the first contact and the second contact based on a force applied to the force sensor;
wherein a response relationship of the force sensor is continuous as a radius of a circular region where the force is applied to the force sensor varies.

2. The force sensor of claim 1, wherein the force sensitive material is deposed between the first contact and the second contact.

3. The force sensor of claim 1, wherein the force sensitive material is deposed on a layer above or below the first contact and the second contact.

4. The force sensor of claim 1, wherein the force sensitive material is deposited on a second substrate and pressed against the first contact and the second contact.

5. The force sensor of claim 1 wherein the force sensitive material passes current between the first contact and the second contact wherein the current changes with the force applied.

6. The force sensor of claim 1, a voltage between the first contact and the second contact changes with the force applied.

7. The force sensor of claim 1, wherein the first spiral pattern and the second spiral pattern have a constant separation.

8. The force sensor of claim 1, wherein a space between the first spiral pattern and the second spiral pattern increases exponentially as the first spiral pattern and the second spiral pattern expand from a center.

9. The force sensor of claim 1, wherein a thickness of the first spiral pattern and the second spiral pattern increases as first spiral pattern and the second spiral pattern expands away from a center point.

10. The force sensor of claim 1, wherein a center area of the first spiral pattern and the second spiral pattern is free of contacts.

11. The force sensor of claim 1, wherein a line width of the first spiral pattern and the second spiral pattern vary with location on the first spiral pattern and the second spiral pattern.

12. The force sensor of claim 11, wherein the line width varies exponentially with location.

13. The force sensor of claim 1, further including an interleaved third spiral pattern electrically coupled with the first spiral pattern and an interleaved fourth spiral pattern electrically coupled with the second spiral pattern.

14. A method of forming an electrode pattern with a continuous response curve, comprising:
determining a spiral curve based on a set of parameters;
drawing a plurality of interleaved spirals based on the spiral curve; and
depositing contacts on a substrate corresponding to the plurality of interleaved spirals.

15. The method of claim 14, further including depositing a force sensitive material on the contacts.

16. The method of claim 14, wherein drawing a plurality of interleaved spirals based on the spiral curve includes
drawing a first spiral curve; and
drawing a second spiral curve identical to the first spiral curve rotated around a center by an angle.

17. The method of claim 16, wherein the angle is 180°.

18. The method of claim 16, wherein the angle is 360°/N, where N is the number of spiral curves.

19. The method of claim 16, wherein the set of parameters is determined to provide a response curve.

20. The method of claim 19, wherein the spiral curve is an exponentially increasing spiral.

21. The method of claim 19, wherein the spiral curve is an exponentially decreasing spiral.

22. A force sensor comprising:
a substrate;
a force sensitive material disposed on the substrate; and
means for monitoring the force sensitive material with first and second contacts such that a continuous response relationship of the force sensor results.

23. The force sensor of claim 22 wherein the means for monitoring the force sensitive material includes
means for determining current between the first contact and the second contact wherein the current changes with the force applied.

24. The force sensor of claim 22, wherein the means for monitoring the force sensitive material includes
means for determining a voltage between the first contact and the second contact wherein the voltage changes with the force applied.

25. The force sensor of claim 22, wherein the response curve illustrates sensitivity that decreases with increasing force.

26. The force sensor of claim 22, wherein the response curve illustrates sensitivity that increases with increasing force.

27. The force sensor of claim 22, wherein the means for monitoring the force sensitive material with first and second contacts comprises:
means for providing a first contact adjacent the force sensitive material; and
means for providing a second contact adjacent the force sensitive material and proximate to the first contact.

28. A computer readable medium storing instructions for forming an electrode pattern with a continuous response curve, comprising:
determining a spiral curve based on a set of parameters;
drawing a plurality of interleaved spirals based on the spiral curve,
wherein the plurality of interleaved spirals can be deposited on a substrate.

29. The medium of claim 28, wherein drawing a plurality of interleaved spirals based on the spiral curve includes
drawing a first spiral curve; and
drawing a second spiral curve identical to the first spiral curve rotated around a center by an angle.

30. The medium of claim 28, wherein the angle is 360°/N, where N is the number of spiral curves.
